(19) United States
(12) Patent Application Publication
(10) Pub. No.: US 2024/0170330 A1
(43) Pub. Date: May 23, 2024

(54) SUBSTRATE AND MANUFACTURING METHOD FOR THE SAME

(71) Applicant: SAMSUNG ELECTRO-MECHANICS CO., LTD., Suwon-si (KR)

(72) Inventors: Chanhoon Ko, Suwon-si (KR); Sanghoon Kim, Suwon-si (KR); Young Kuk Ko, Suwon-si (KR); Chulmin Lee, Suwon-si (KR); Inhwan Oh, Suwon-si (KR); Kyounghee Lim, Suwon-si (KR); Sohyun Bae, Suwon-si (KR)

(73) Assignee: SAMSUNG ELECTRO-MECHANICS CO., LTD., Suwon-si (KR)

(21) Appl. No.: 18/206,885

(22) Filed: Jun. 7, 2023

(30) Foreign Application Priority Data
Nov. 18, 2022 (KR) 10-2022-0155642

(51) Int. Cl. H01L 21/768; H01L 23/528

(52) U.S. Cl. CPC H01L 21/76894; H01L 23/5283

(57) ABSTRACT

A substrate including: an insulation layer; a conductive layer disposed on the insulation layer; and a via hole configured to include a lower hole disposed in a first portion of the insulation layer and an upper hole disposed in a second portion of the insulating layer and connected to the lower hole, wherein a width of the upper hole is greater than that of the lower hole, at least a portion of the upper hole of the insulation layer has a width that is substantially equal to that of the upper hole of the conductive layer, and a first angle formed between a first direction that is parallel to a lower surface of the insulating layer and a sidewall of the lower hole and a second angle formed between the first direction and a sidewall of the upper hole are different from each other.

### CROSS-REFERENCE TO RELATED APPLICATION

This application claims priority to and the benefit of Korean Patent Application No. 10-2022-0155642, filed in the Korean Intellectual Property Office on Nov. 18, 2022, the entire content of which is incorporated herein by reference.

### BACKGROUND

### 1. Technical Field

The present disclosure relates to a substrate and a manufacturing method thereof.

### 2. Description of the Related Art

Holes are formed in a substrate for electrical connection between layers of the substrate. Many methods of using lasers to form the holes in the substrate have been proposed.

When using a laser to form a hole in a substrate, the hole may have a structure that becomes narrower as it goes upward, or an upper metal layer may protrude more than a lower insulation layer, due to a difference in thermal conduction and laser absorption between the insulation layer and the metal layer of the substrate, and as a result, the metal layer for connection may not be completely filled in the hole, or a yield may be lowered, such as because of the occurrence of voids.

The above information disclosed in this Background section is only for enhancement of understanding of the background of the described technology, and therefore, it may contain information that does not form the prior art that is already known in this country to a person of ordinary skill in the art.

### SUMMARY

Embodiments have been made in an effort to provide a substrate having a hole and a manufacturing method thereof, capable of preventing occurrence of a defect in a metal layer filled in a via hole by preventing a width of the via hole from narrowing upward or preventing an upper metal layer from protruding more than a lower insulation layer within the via hole.

However, the problem to be solved by the embodiments is not limited to the above-described problem, and can be variously extended within the scope of the technical spirit included in the embodiments.

An embodiment provides a substrate including: an insulation layer; a conductive layer disposed on the insulation layer; and a via hole configured to include: a lower hole disposed in a first portion of the insulation layer, and an upper hole disposed in a second portion of the insulating layer disposed above the first portion of the insulation layer and in the conductive layer and connected to the lower hole, wherein a width of the upper hole is greater than that of the lower hole, at least a portion of the upper hole in the second portion has a first width that is substantially equal to a second width of the upper hole in the conductive layer, and a first angle between a first direction that is parallel to a lower surface of the insulating layer and a sidewall of the lower hole and a second angle between the first direction and a sidewall of the upper hole are different from each other.

The via hole may further include a middle hole disposed between the lower hole and the upper hole, and a third angle between the first direction and a sidewall of the middle hole may be different from the first angle and the second angle.

The first angle may be smaller than the second angle and greater than the third angle.

A cross-section of the sidewall of the middle hole may have a curved shape.

The substrate may include: a lower conduction pattern disposed below the first portion; and an upper conductive pattern disposed on the conductive layer, wherein the lower hole may have a first width at a portion closer to the lower conductive pattern than a second width that is greater than the first width, the second width is disposed at a portion closer to the upper conductive pattern than the first width, and the width of the upper hole is greater than a maximum width of the lower hole.

The lower hole may have a lower width at a portion in contact with the lower conductive pattern, the upper hole may have an upper width at a portion in contact with the upper conductive pattern, and a ratio of the upper width to the lower width may be greater than about 1 and equal to or smaller than about 3.

The substrate may include a connection conductive pattern disposed within the via hole and connected to the lower conductive pattern and the upper conductive pattern.

The insulation layer further includes a first insulation layer disposed in the second portion, and the upper hole may be disposed in the first insulation layer and the conductive layer.

The substrate may include a first insulation layer disposed between the insulation layer and the conductive layer, the upper hole may further include a portion in the first insulation layer, and the width of the upper hole in the first insulation layer may be approximately equal to the width of the upper hole in the conductive layer.

An embodiment provides a substrate including: an insulation layer; a conductive layer disposed on the insulation layer; and a via hole configured to include: a lower hole disposed in a first portion of the insulation layer, an upper hole disposed in a second portion of the insulating layer disposed above the first portion of the insulation layer and in the conductive layer, and a middle hole disposed between the lower hole and the upper hole, wherein a width of the upper hole is greater than that of the lower hole, a first width of the upper hole in the second portion and a second width of the upper hole in the conductive layer are substantially equal to each other, and a cross-section of a sidewall of the middle hole has a curved shape.

A central portion of the lower hole and a central portion of the upper hole may not be vertically aligned.

An embodiment provides a manufacturing method of a substrate, including: forming an insulation layer; forming a conductive layer on the insulating layer; forming a first hole by first removing the conductive layer and the insulation layer by irradiating a first laser; forming a second hole by second removing the insulation layer by irradiating a second laser; and forming a third hole by third removing the conductive layer and the insulation layer by irradiating a third laser.

The first laser and the third laser may be YAG lasers, and the second laser may be a carbon dioxide gas laser.

The conductive layer may be hardly removed in the irradiating of the second laser.

The insulation layer may be impregnated with a glass fiber, and the glass fiber of the insulating layer may be processed in the irradiating of the second laser.

A width of the first hole in the conductive layer may be formed to be narrower than a width of the second hole in the insulation layer before the irradiating of the third laser.

A width of the third hole in the conductive layer and a width of the third hole in the insulating layer may be formed to be substantially the same in the irradiating of the third laser.

An embodiment provides a substrate including: an insulation layer; a conductive layer disposed on the insulation layer; and a via hole configured to include: a lower hole disposed in a first portion of the insulation layer, and an upper hole disposed in a second portion of the insulating layer disposed above the first portion of the insulation layer and in the conductive layer and connected to the lower hole, wherein a width of the upper hole is greater than that of the lower hole, and a sidewall of the upper hole in the second portion and the conductive layer extend along a thickness direction of the substrate.

A sidewall of the lower hole may extend at an angle relative to the thickness direction.

The conductive layer may not protrude toward an interior of the via hole.

According to the embodiments, it is possible to provide a substrate having a hole and a manufacturing method thereof, capable of preventing occurrence of a defect in a metal layer filled in a via hole by preventing a width of the via hole from narrowing upward or preventing an upper metal layer from protruding more than a lower insulation layer within the via hole.

However, it is obvious that the effect of the embodiments is not limited to the above-described effect, and may be variously extended without departing from the spirit and scope of the embodiments.

### BRIEF DESCRIPTION OF THE DRAWINGS

FIG. 1 illustrates a cross-sectional view of a substrate according to an embodiment.

FIG. 2 to FIG. 4 illustrate cross-sectional views showing a manufacturing method of a substrate according to an embodiment.

FIG. 5 illustrates a cross-sectional view of a substrate according to another embodiment.

FIG. 6 to FIG. 8 illustrate cross-sectional views showing a manufacturing method of a substrate according to another embodiment.

FIG. 9 illustrates a cross-sectional view of a substrate according to another embodiment.

FIG. 10 illustrates a cross-sectional view of a substrate according to another embodiment.

### DETAILED DESCRIPTION

The present disclosure will be described more fully hereinafter with reference to the accompanying drawings, in which embodiments are shown. As those skilled in the art would realize, the described embodiments may be modified in various different ways, all without departing from the spirit or scope of the present disclosure.

To clearly describe the embodiments, parts that are irrelevant to the description are omitted, and like numerals refer to like or similar constituent elements throughout the specification.

The accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., may be exaggerated for clarity. In the drawings, for better understanding and ease of description, the thicknesses of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, “connected” means that two or more components are not only directly connected, but two or more components may be connected indirectly through other components, physically connected as well as being electrically connected, or it may be referred to by different names depending on the location or function, but may mean integral.

Hereinafter, various embodiments and variations will be described in detail with reference to drawings.

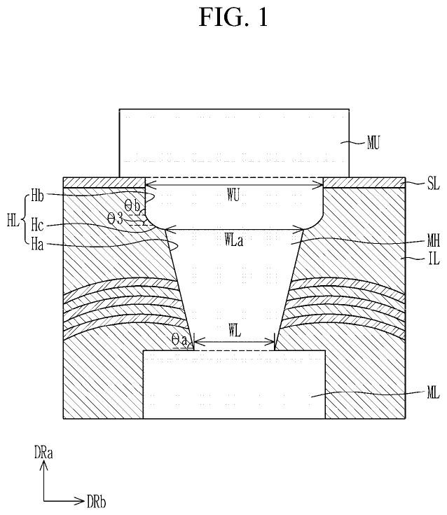

Hereinafter, a substrate according to an embodiment will be described with reference to FIG. 1. FIG. 1 illustrates a cross-sectional view of a substrate according to an embodiment.

Referring to FIG. 1, a substrate according to an embodiment may include: a lower conductive pattern ML; an insulation layer IL disposed on the lower conductive pattern ML along a first direction DRa, which is a height direction; a conductive layer SL disposed on the insulation layer IL along the first direction DRa; an upper conductive pattern MU disposed on the conductive layer SL along the first direction DRa; a via hole HL formed in the insulation layer IL and the conductive layer SL; and a connection conductive pattern MH disposed in the via hole HL.

The lower conductive pattern ML and the upper conductive pattern MU may be connected to each other through the connection conductive pattern MH disposed in the via hole HL formed in the insulation layer IL and the conductive layer SL.

The insulation layer IL may include an insulating material, and may include a filler or reinforcing agent. The insulation layer IL may include a prepreg (PPG), and may be impregnated with glass fibers. However, the present disclosure is not limited thereto, and the insulation layer IL may include insulating materials.

The conductive layer SL may be a metal coil layer or, e.g., a copper coil layer, but the present disclosure is not limited thereto.

The via hole HL formed in the insulation layer IL and the conductive layer SL may include a lower hole Ha contacting the lower conductive pattern ML, and an upper hole Hb contacting the upper conductive pattern MU. Along the first direction DRa, the upper hole Hb is disposed above the lower hole Ha, and the lower hole Ha and the upper hole Hb are connected to each other through a middle hole Hc. A width of the upper hole Hb may be greater than that of the lower hole Ha along a second direction DRb that is perpendicular to the first direction DRa. Hereinafter, all widths are assumed to be measured along the second direction DRb, even when not specifically mentioned. The widths may be measured using microscopy techniques such as SEM, TEM, and optical microscopy. Other methods and/or tools appreciated by one of ordinary skill in the art, even if not described in the present disclosure, may also be used.

The lower hole Ha may be formed in a lower portion of the insulation layer IL, and the upper hole Hb may be formed in an upper portion of the insulating layer IL and the conductive layer SL.

A width of the lower hole Ha may gradually widen as it approaches the upper conductive pattern MU from a portion contacting the lower conductive pattern ML. According to the illustrated embodiment, the width of the lower hole Ha is shown to continuously gradually widen as it approaches the upper conductive pattern MU from a portion contacting the lower conductive pattern ML, but the present disclosure is not limited thereto, and a sidewall of the lower hole Ha may include a partially protruding portion, and accordingly, the width of the lower hole Ha may include a portion that is narrower at the top than at the bottom.

A maximum width WLa of the lower hole Ha may be greater than a lower width WL of the portion in contact with the lower conductive pattern ML of the lower hole Ha, and may be smaller than an upper width WU of a portion of the upper hole Hb contacting the upper conductive pattern MU.

A ratio of the upper width WU of the portion in contact with the upper conductive pattern MU of the upper hole Hb to the lower width WL of the portion in contact with the lower conductive pattern ML of the lower hole Ha may be greater than about 1 and equal to or smaller than about 3.

A first angle θa formed between a second direction DRb substantially parallel to a lower surface of the insulation layer IL and a sidewall of the lower hole Ha and a second angle θb formed between a second direction DRb and the sidewall of the upper hole Hb may be different from each other. For example, the second angle θb may be greater than the first angle θa. Taper angles of the lower hole Ha and the upper hole Hb may be different from each other. When an angle at which the sidewall is inclined with respect to the first direction DRa is also referred to as a taper angle, the taper angle of the lower hole Ha may be greater than that of the upper hole Hb. The angles may be obtained by applying a image processing software to the micrographs of the cross-section of the substrate measured using microscopy techniques such as SEM, TEM, and optical microscopy. Other methods and/or tools appreciated by one of ordinary skill in the art, even if not described in the present disclosure, may also be used.

According to the illustrated embodiment, sidewalls of the lower hole Ha and the upper hole Hb are illustrated as having almost straight cross-sections, but the present disclosure is not limited thereto, and as described above, the sidewalls of the lower hole Ha and the upper hole Hb may include some protruding portions, and the sidewalls of the lower hole Ha and the upper hole Hb may not be flat.

A thickness of the middle hole Hc between the lower hole Ha and the upper hole Hb may be smaller than that of the lower hole Ha and the upper hole Hb, and a cross-section of the sidewall of the middle hole Hc may have a curved shape. In addition, since the cross-section of the sidewall of the middle hole Hc has the curved shape, a third angle θ3 formed by the second direction DRb and the sidewall of the middle hole Hc may change depending on a position. However, the third angle θ3 may be smaller than the first angle θa and the second angle θb. Accordingly, the taper angles of the lower hole Ha, the upper hole Hb, and the middle hole Hc may be different from each other. When an angle at which the sidewall is inclined with respect to the first direction DRa is also referred to as a taper angle, the taper angle of the middle hole Hc may be greater than the taper angle of the lower hole Ha and the taper angle of the upper hole Hb. The taper angles of the lower hole Ha, the upper hole Hb, and the middle hole Hc may have smaller sizes in an order of the middle hole Hc, the lower hole Ha, and the upper hole Hb.

When a width of the upper hole Hb is smaller than that of the lower hole Ha, when the connection conductive pattern MH is formed in the via hole HL, defects such as not completely filling the connection conductive pattern MH or forming unnecessary voids may occur. However, in accordance with a substrate according to the present embodiment, the width of the upper hole Hb may be greater than that of the lower hole Ha, so that when the connection conductive pattern MH is formed in the via hole HL, a defect may not occur.

In the upper hole Hb formed in the insulating layer IL, a width of the upper hole Hb disposed at an upper side and the width of the upper hole Hb formed in the conductive layer SL may be substantially the same. When the width of the upper hole Hb formed in the conductive layer SL is smaller than the width of the upper hole Hb formed in the insulation layer IL, an edge of the conductive layer SL protrudes, and when the connection conductive pattern MH is formed in the upper hole Hb by plating or the like, a plating seed layer may be broken at a boundary between the conductive layer SL and the insulation layer IL, the connection conductive pattern MH may not be completely filled, or defects such as formation of unnecessary voids may occur. However, in accordance with a substrate according to the present embodiment, the width of the upper hole Hb formed in the conductive layer SL may be substantially the same as that of the upper hole Hb formed in the insulation layer IL, and thus defects in the connection conductive pattern MH that may occur at an interface between the insulation layer IL and the conductive layer SL may be prevented.

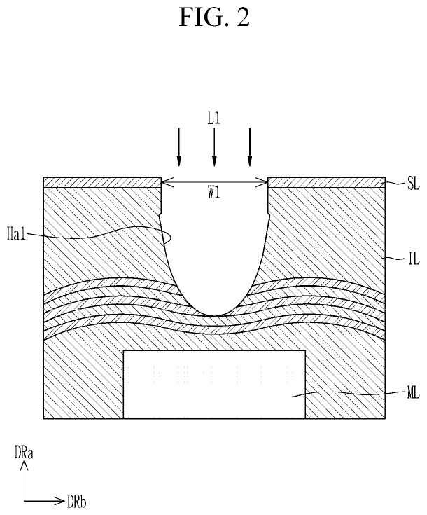

Hereinafter, a manufacturing method of a substrate according to an embodiment will be described with reference to FIG. 2 to FIG. 4 together with FIG. 1. FIG. 2 to FIG. 4 illustrate cross-sectional views showing a manufacturing method of a substrate according to an embodiment.

Referring to FIG. 2, the lower conductive pattern ML is formed, the insulation layer IL is stacked on the lower conductive pattern ML, and then the conductive layer SL is formed on the insulation layer IL, and then the conductive layer SL and the insulation layer IL are removed by irradiation with a first laser L1, and a first subhole Ha1 is formed in the conductive layer SL and the insulation layer IL.

The first laser L1 may be a YAG laser.

An uppermost portion of the first subhole Ha1 may have a first width W1, the first subhole Ha1 may be formed in a portion of the conductive layer SL and the insulating layer IL, the lower conductive pattern ML may not be exposed by the first subhole Ha1, and a portion of the insulation layer IL may remain on the lower conductive pattern ML.

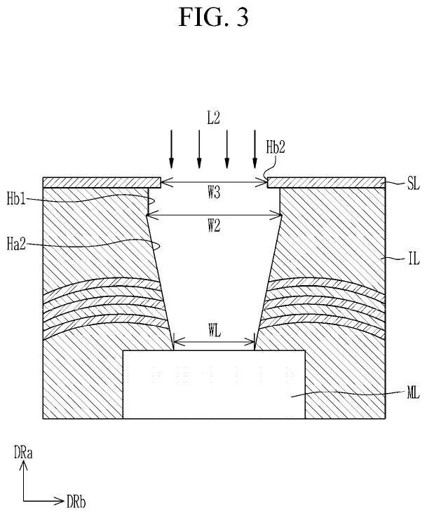

Next, referring to FIG. 3, the second laser beam L2 is irradiated to further remove the insulating layer IL outside the first subhole Ha1, and the second subhole Ha2 and a third subhole Hb1 are formed in the insulating layer IL to expose the lower conductive pattern ML.

The second laser L2 may be a carbon dioxide (CO₂) gas laser. When the insulation layer IL is removed by using the second laser L2, glass fibers in the insulation layer IL may be processed, and accordingly, unnecessary glass powder or glass particles may be prevented from being generated.

The second subhole Ha2 of the insulation layer IL may have the lower width WL at a portion in contact with the lower conductive pattern ML, the third subhole Hb1 of the insulation layer IL may have the second width W2, the fourth subhole Hb2 of the conductive layer SL disposed on the insulation layer IL may have the third width W3, and the third width W3 may be smaller than the second width W2 and may be substantially equal to the first width W1.

The second subhole Ha2 of the insulation layer IL may be the lower hole Ha of the via hole HL.

As such, when the insulating layer IL is additionally removed by irradiating the second laser L2, the conductive layer SL is not removed or is less removed than the insulating layer IL, and thus the fourth subhole Hb2 of the conductive layer SL may be formed narrower than the third subhole Hb1 of the insulating layer IL, and the conductive layer SL may protrude toward a center of the hole rather than the insulation layer IL.

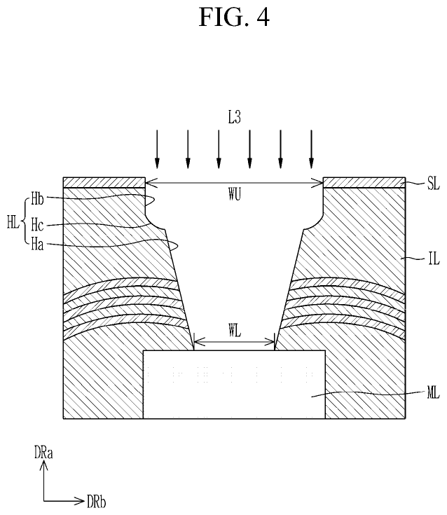

Next, referring to FIG. 4, the insulation layer IL and the conductive layer SL around the third subhole Hb1 of the insulation layer IL and the fourth subhole Hb2 of the conductive layer SL may be additionally removed by irradiating the third laser L3, so that the upper hole Hb disposed above the lower hole Ha of the via hole HL and having the upper width WU may be formed. In addition, the middle hole Hc connecting the lower hole Ha and the upper hole Hb may be formed. Accordingly, the via hole HL including the lower hole Ha and the upper hole Hb may be completed.

The third laser L3 may be a YAG laser. Both the conductive layer SL and the insulation layer IL may be removed by irradiating the third laser L3, so that the width of the upper hole Hb formed in the insulation layer IL and the width of the upper hole Hb formed in the conductive layer SL may be substantially the same.

Next, a metal layer may be formed in the via hole HL including the lower hole Ha and the upper hole Hb by plating or the like to form the connection conductive pattern MH in the via hole HL, and a substrate according to the embodiment illustrated in FIG. 1 may be formed by forming the upper conductive pattern MU thereon.

In accordance with a manufacturing method of a substrate according to the present embodiment, the first subhole Ha1 may be formed by removing the insulation layer IL and the conductive layer SL using a first laser beam L1, the second subhole Ha2 constituting the lower hole Ha and the third subhole Hb1 above the second subhole Ha2 may be formed in the insulation layer IL by secondarily removing the insulation layer IL using the second laser L2, and upper holes Hb having the same width may be formed in the conductive layer SL and the insulation layer IL, so that the via hole HL including the lower hole Ha and the upper hole Hb may be formed.

Accordingly, the width of the upper hole Hb may be greater than that of the lower hole Ha, and the via hole HL may be formed such that the width of the upper hole Hb formed in the insulation layer IL and the width of the upper hole Hb formed in the conductive layer SL are substantially the same.

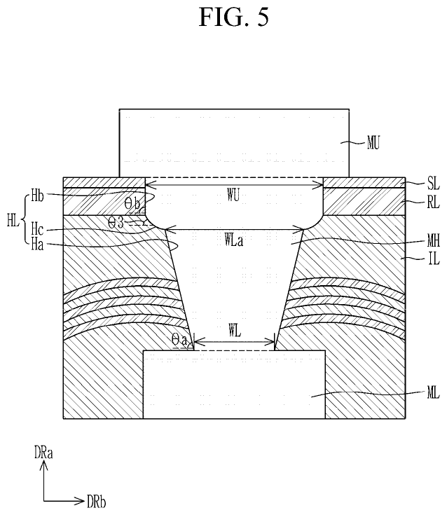

Hereinafter, a substrate according to another embodiment will be described with reference to FIG. 5. FIG. 5 illustrates a cross-sectional view of a substrate according to another embodiment.

Referring to FIG. 5, the substrate according to the present embodiment is similar to the substrate according to the embodiment described with reference to FIG. 1. A detailed description of the same constituent elements will be omitted.

Unlike the embodiment illustrated in FIG. 1, the substrate according to the present embodiment may further include a first insulation layer RL disposed between the insulation layer IL and the conductive layer SL.

The insulation layer IL may include an insulating material, and may include a filler or reinforcing agent. The insulating layer IL may include a prepreg (PPG), and may be impregnated with glass fibers. However, the present disclosure is not limited thereto, and the insulation layer IL may include insulating materials.

The first insulation layer RL may include an insulating material, and may not include a filler or reinforcing agent. The first insulation layer RL may be a primer resin layer, and the first insulation layer RL may include one or more epoxy resins selected from a naphthalene-based epoxy resin, a bisphenol A-type epoxy resin, a phenol novolak epoxy resin, a cresol novolac epoxy resin, a rubber-modified epoxy resin, and a phosphorous-based epoxy resin. However, the present disclosure is not limited thereto, and the first insulation layer RL may include various materials.

The conductive layer SL may be a metal coil layer or, e.g., a copper coil layer, but the present disclosure is not limited thereto.

The substrate according to the present embodiment may further include a first insulation layer RL, thereby increasing adherence between the insulation layer IL and the conductive layer SL.

The via hole HL may be formed in the insulation layer IL, the first insulation layer RL, and the conductive layer SL, and may include the lower hole Ha contacting the lower conductive pattern ML and the upper hole Hb contacting the upper conductive pattern MU. The lower hole Ha and the upper hole Hb may be connected to each other, and a width of the upper hole Hb may be greater than that of the lower hole Ha.

The lower hole Ha may be formed in the insulation layer IL, and the upper hole Hb may be formed in the first insulation layer RL and the conductive layer SL. The middle hole Hc between the lower hole Ha and the upper hole Hb may be formed in a portion of the insulation layer IL, but the present disclosure is not limited thereto, and the middle hole Hc may be formed at a lower portion of the first insulation layer RL.

A width of the lower hole Ha may gradually widen as it approaches the upper conductive pattern MU from a portion contacting the lower conductive pattern ML. According to the illustrated embodiment, the width of the lower hole Ha is shown to continuously gradually widen as it approaches the upper conductive pattern MU from a portion contacting the lower conductive pattern ML, but the present disclosure is not limited thereto, and a sidewall of the lower hole Ha may include a partially protruding portion, and accordingly, the width of the lower hole Ha may include a portion that is narrower at the top than at the bottom.

A maximum width WLa of the lower hole Ha may be greater than a lower width WL of the portion in contact with the lower conductive pattern ML of the lower hole Ha, and may be smaller than an upper width WU of a portion of the upper hole Hb contacting the upper conductive pattern MU.

A ratio of the upper width WU of the portion in contact with the upper conductive pattern MU of the upper hole Hb to the lower width WL of the portion in contact with the lower conductive pattern ML of the lower hole Ha may be greater than about 1 and equal to or smaller than about 3.

The width of the upper hole Hb formed in the first insulation layer RL and the width of the upper hole Hb formed in the conductive layer SL may be substantially the same.

A first angle θa formed between a second direction DRb substantially parallel to a lower surface of the insulation layer IL and a sidewall of the lower hole Ha and a second angle θb formed between a second direction DRb and the sidewall of the upper hole Hb may be different from each other. For example, the second angle θb may be greater than the first angle θa. Taper angles of the lower hole Ha and the upper hole Hb may be different from each other. When an angle inclined with respect to the first direction DRa is also referred to as a taper angle, the taper angle of the lower hole Ha may be greater than that of the upper hole Hb.

According to the illustrated embodiment, sidewalls of the lower hole Ha and the upper hole Hb are illustrated as having almost straight cross-sections, but the present disclosure is not limited thereto, and as described above, the sidewalls of the lower hole Ha and the upper hole Hb may include some protruding portions, and the sidewalls of the lower hole Ha and the upper hole Hb may not be flat.

A thickness of the middle hole Hc between the lower hole Ha and the upper hole Hb may be smaller than that of the lower hole Ha and the upper hole Hb, and a cross-section of the sidewall of the middle hole Hc may have a curved shape. In addition, since the cross-section of the sidewall of the middle hole Hc has the curved line shape, a third angle θ3 formed by the second direction DRb and the sidewall of the middle hole Hc may change depending on a position, but the third angle θ3 may be smaller than the first angle θa and the second angle θb. Accordingly, the taper angles of the lower hole Ha, the upper hole Hb, and the middle hole Hc may be different from each other. When an angle at which the sidewall is inclined with respect to the first direction DRa is also referred to as a taper angle, the taper angle of the middle hole Hc may be greater than the taper angle of the lower hole Ha and the taper angle of the upper hole Hb. The taper angles of the lower hole Ha, the upper hole Hb, and the middle hole Hc may have smaller sizes in an order of the middle hole Hc, the lower hole Ha, and the upper hole Hb.

In accordance with a substrate according to the present embodiment, the width of the upper hole Hb may be greater than that of the lower hole Ha, and when the connection conductive pattern MH is formed in the via hole HL, a defect may not occur. In addition, widths of the upper hole Hb formed in the first insulating layer RL and the conductive layer SL may be substantially the same, and thus when there is a difference in width between the upper hole Hb of the first insulation layer RL and the upper hole Hb of the conductive layer SL, defects in the connection conductive pattern MH, which may occur at an interface between the first insulation layer RL and the conductive layer SL, may be prevented.

Many features of the substrate according to the embodiment described above with reference to FIG. 1 are all applicable to the substrate according to the present embodiment.

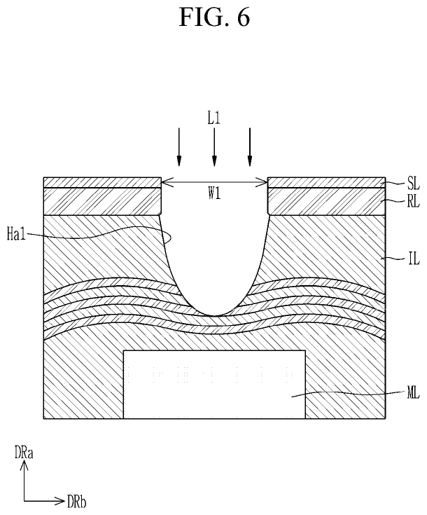

Hereinafter, a manufacturing method of a substrate according to another embodiment will be described with reference to FIG. 6 to FIG. 8 together with FIG. 5. FIG. 6 to FIG. 8 illustrate cross-sectional views showing a manufacturing method of a substrate according to another embodiment.

Referring to FIG. 6, the lower conductive pattern ML is formed, the insulation layer IL is stacked on the lower conductive pattern ML, and then the first insulation layer RL and the conductive layer SL are formed on the insulation layer IL, and then the conductive layer SL, the first insulation layer RL, and the insulation layer IL are removed by irradiation with the first laser L1, and the first subhole Ha1 is formed in the conductive layer SL, the first insulation layer RL, and the insulation layer IL.

The first laser L1 may be a YAG laser.

The first subhole Ha1 may have the first width W1, the first subhole Ha1 may be formed in a portion of the insulating layer IL, the lower conductive pattern ML may not be exposed by the first subhole Ha1, and a portion of the insulation layer IL may remain on the lower conductive pattern ML.

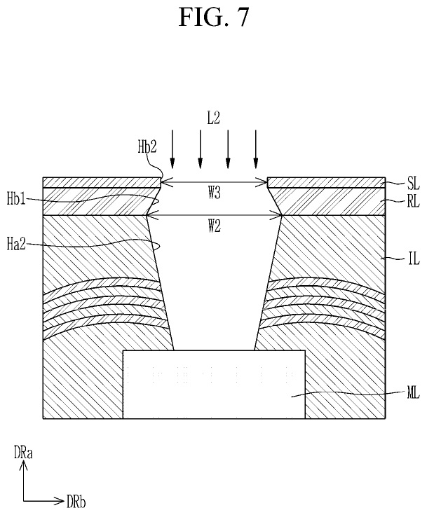

Next, referring to FIG. 7, the second laser beam L2 is irradiated to further remove the insulating layer IL outside the first subhole Ha1, and the second subhole Hb2 are formed in the insulating layer IL to expose the lower conductive pattern ML. In this case, a portion of the first insulation layer RL may also be removed to form the third subhole Hb1 in the first insulation layer RL.

The second laser L2 may be a carbon dioxide (CO₂) gas laser. When the insulation layer IL is removed by using the second laser L2, glass fibers in the insulation layer IL may be processed, and accordingly, unnecessary glass powder or glass particles may be prevented from being generated.

The third subhole Hb1 of the first insulation layer RL may have a structure in which a width decreases from bottom to top. The first insulation layer RL may have lower reactivity to the second laser L2 than the insulation layer IL, and the second laser L2 may be supplied through the gap between the insulating layer IL and the first insulating layer RL, and thus the third subhole Hb1 formed on the first insulation layer RL may have a structure in which the width is wide at a lower portion adjacent to the insulating layer IL and gradually narrows upward.

The second subhole Ha2 of the insulation layer IL may have the lower width WL at a portion in contact with the lower conductive pattern ML, the second subhole Ha2 of the insulation layer IL and the third subhole Hb1 of the first insulation layer RL may have a maximum width of the second width W2, the fourth subhole Hb2 of the conductive layer SL may have the third width W3. and the third width W3 may be smaller than the second width W2 and may be substantially equal to the first width W1.

The second subhole Ha2 of the insulation layer IL may be the lower hole Ha of the via hole HL.

As such, when the insulating layer IL is additionally removed by irradiating the second laser L2, the conductive layer SL is not removed or less removed than the insulating layer II, and thus the fourth subhole Hb2 of the conductive layer SL may be formed narrower than the second subhole Ha2 of the insulating layer IL, and the conductive layer SL may protrude toward a center of the hole rather than the insulation layer IL. In addition, the third subhole Hb1 of the first insulation layer RL may have a structure in which a width decreases from bottom to top.

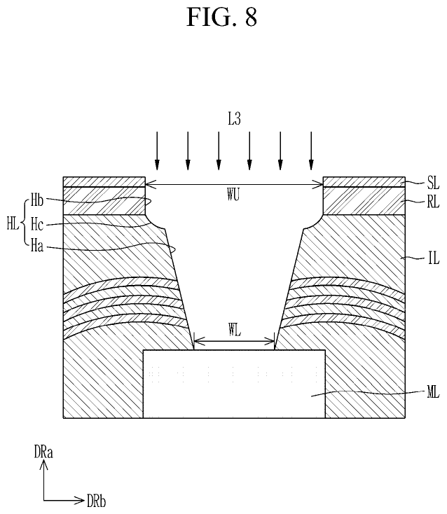

Next, referring to FIG. 8, the first insulation layer RL and the conductive layer SL around the third subhole Hb1 of the first insulation layer RL and the fourth subhole Hb2 of the conductive layer SL may be additionally removed by irradiating the third laser L3, so that the upper hole Hb disposed above the lower hole Ha of the via hole HL and having the upper width WU may be formed. In addition, the middle hole Hc may be formed between the lower hole Ha and the upper hole Hb. Accordingly, the via hole HL including the lower hole Ha and the upper hole Hb may be completed.

The third laser L3 may be a YAG laser. Both the first insulation layer RL and the insulation layer IL may be removed by irradiating the third laser L3, so that the width of the upper hole Hb formed in the first insulation layer RL and the width of the upper hole Hb formed in the conductive layer SL may be substantially the same.

Next, a metal layer may be formed in the via hole HL including the lower hole Ha and the upper hole Hb by plating or the like to form the connection conductive pattern MH in the via hole HL, and a substrate illustrated in FIG. 5 may be formed by forming the upper conductive pattern MU thereon.

In accordance with a manufacturing method of a substrate according to the present embodiment, the first subhole Ha1 is formed by removing the insulation layer IL, the first insulation layer RL, and the conductive layer SL using the first laser beam L1, the third subhole Hb1 of the first insulation layer RL may be formed at a same time as forming the second subhole Ha2 constituting the lower hole Ha in the insulation layer IL by secondly removing the insulation layer IL using the second laser L2, and upper holes Hb having same widths as each other may be formed in the conductive layer SL and the first insulation layer RL by thirdly removing of the conductive layer SL and the first insulating layer RL together using the third laser L3, so that the via hole HL including the lower hole Ha and the upper hole Hb may be formed.

Accordingly, the width of the upper hole Hb may be greater than that of the lower hole Ha, and the via hole HL may be formed such that the width of the upper hole Hb formed in the first insulation layer RL and the width of the upper hole Hb formed in the conductive layer SL are substantially the same.

Many features of the substrate manufacturing method according to the embodiment described above with reference to FIG. 2 to FIG. 4 together with FIG. 1 are all applicable to the substrate manufacturing method according to the present embodiment.

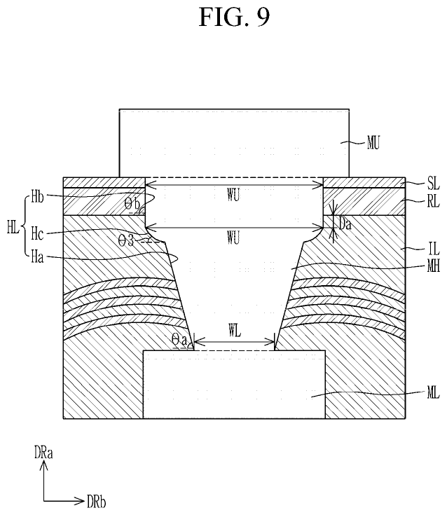

Hereinafter, a substrate according to another embodiment will be described with reference to FIG. 9. FIG. 9 illustrates a cross-sectional view of a substrate according to another embodiment.

Referring to FIG. 9, the substrate according to the present embodiment is similar to the substrate according to the embodiment illustrated in FIG. 5. A detailed description of the same constituent elements will be omitted.

As illustrated in FIG. 9, the via hole HL may be formed in the insulation layer IL, the first insulation layer RL, and the conductive layer SL, and may include the lower hole Ha contacting the lower conductive pattern ML and the upper hole Hb contacting the upper conductive pattern MU. The lower hole Ha and the upper hole Hb may be connected to each other, and a width of the upper hole Hb may be greater than that of the lower hole Ha.

The lower hole Ha may be formed in the insulation layer IL, and the upper hole Hb may be formed in a portion of the insulation layer IL as well as the first insulation layer RL and the conductive layer SL. The middle hole Hc between the lower hole Ha and the upper hole Hb may be formed in a portion of the insulation layer IL.

A width of the lower hole Ha may gradually widen as it approaches the upper conductive pattern MU from a portion contacting the lower conductive pattern ML.

A maximum width WLa of the lower hole Ha may be greater than a lower width WL of the portion in contact with the lower conductive pattern ML of the lower hole Ha, and may be smaller than an upper width WU of a portion of the upper hole Hb contacting the upper conductive pattern MU.

A ratio of the upper width WU of the portion in contact with the upper conductive pattern MU of the upper hole Hb to the lower width WL of the portion in contact with the lower conductive pattern ML of the lower hole Ha may be greater than about 1 and equal to or smaller than about 3.

The width of the upper hole Hb formed in the first insulation layer RL, the width of the upper hole Hb formed in the conductive layer SL, and the width of the upper hole Hb formed in the insulation layer IL may be substantially the same.

According to the present embodiment, unlike in the embodiment illustrated in FIG. 5, the lower hole Ha may be formed in a portion of the insulating layer IL, and the upper hole Hb may be formed not only in the first insulation layer RL and the conductive layer SL, but also in a portion of the insulation layer IL.

A depth of the upper hole Hb of the substrate according to the present embodiment may be greater than that of the upper hole Hb of the embodiment illustrated in FIG. 5, by a height difference Da shown in FIG. 9.

According to the present embodiment, a boundary between the lower hole Ha and the upper hole Hb having different widths may be formed inside the insulation layer IL. When interfaces of different layers are disposed at the boundary between the lower hole Ha and the upper hole Hb, different layers may be separated from each other at the interface due to a stress difference generated at the boundary between the lower hole Ha and the upper hole Hb. However, according to the present embodiment, since the boundary between the lower hole Ha and the upper hole Hb having different widths is formed inside the insulation layer IL, it is possible to prevent a film separation defect from occurring at the interface.

Many features of the substrates according to the above-described embodiments are all applicable to the substrate according to the present embodiment.

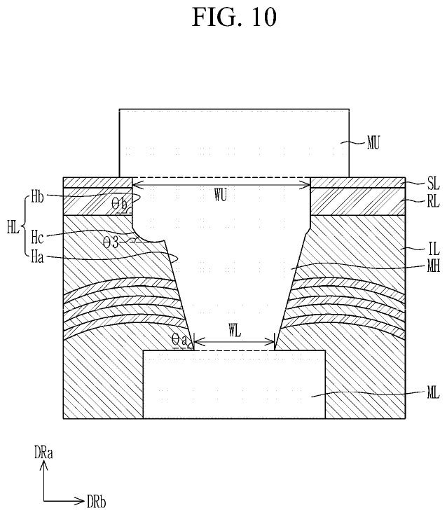

Hereinafter, a substrate according to another embodiment will be described with reference to FIG. 10. FIG. 10 illustrates a cross-sectional view of a substrate according to another embodiment.

Referring to FIG. 10, the substrate according to the present embodiment is similar to the substrate according to the embodiment described with reference to FIG. 9. A detailed description of the same constituent elements will be omitted.

Unlike the substrate according to the embodiment illustrated in FIG. 9, the substrate according to the present embodiment may have a form in which the lower hole Ha and the upper hole Hb of the via hole HL are not aligned but are partially misaligned.

The via hole HL may be formed in the insulation layer IL, the first insulation layer RL, and the conductive layer SL, and may include the lower hole Ha contacting the lower conductive pattern ML and the upper hole Hb contacting the upper conductive pattern MU. The lower hole Ha and the upper hole Hb may be connected to each other, and a width of the upper hole Hb may be greater than that of the lower hole Ha.

The lower hole Ha may be formed in the insulation layer IL, and the upper hole Hb may be formed in a portion of the insulation layer IL as well as the first insulation layer RL and the conductive layer SL.

A width of the lower hole Ha may gradually widen as it approaches the upper conductive pattern MU from a portion contacting the lower conductive pattern ML.

A maximum width WLa of the lower hole Ha may be greater than a lower width WL of the portion in contact with the lower conductive pattern ML of the lower hole Ha, and may be smaller than an upper width WU of a portion of the upper hole Hb contacting the upper conductive pattern MU.

A ratio of the upper width WU of the portion in contact with the upper conductive pattern MU of the upper hole Hb to the lower width WL of the portion in contact with the lower conductive pattern ML of the lower hole Ha may be greater than about 1 and equal to or smaller than about 3.

The width of the upper hole Hb formed in the first insulation layer RL, the width of the upper hole Hb formed in the conductive layer SL, and the width of the upper hole Hb formed in the insulation layer IL may be substantially the same.

Many features of the substrates according to the above-described embodiments are all applicable to the substrate according to the present embodiment.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

HL: via hole
Ha: lower hole
Hb: upper hole
Ha1, Ha2, Hb1, Hb2: subholes
ML: lower conductive pattern
MU: upper conduction pattern
MH: connection challenge pattern
IL: insulation layer
RL: first insulation layer
SL: conductive layer
L1, L2, L3: laser

What is claimed is:

1. A substrate comprising:
an insulation layer;
a conductive layer disposed on the insulation layer; and
a via hole configured to include:
a lower hole disposed in a first portion of the insulation layer, and
an upper hole disposed in a second portion of the insulating layer disposed above the first portion of the insulation layer and in the conductive layer and connected to the lower hole,
wherein a width of the upper hole is greater than that of the lower hole,
at least a portion of the upper hole in the second portion has a first width that is substantially equal to a second width of the upper hole in the conductive layer, and
a first angle between a first direction that is parallel to a lower surface of the insulating layer and a sidewall of the lower hole and a second angle between the first direction and a sidewall of the upper hole are different from each other.

2. The substrate of claim 1, wherein
the via hole further includes a middle hole disposed between the lower hole and the upper hole,
wherein a third angle between the first direction and a sidewall of the middle hole is different from the first angle and the second angle.

3. The substrate of claim 2, wherein
the first angle is smaller than the second angle and greater than the third angle.

4. The substrate of claim 2, wherein
a cross-section of the sidewall of the middle hole has a curved shape.

5. The substrate of claim 1, further comprising:
a lower conduction pattern disposed below the first portion; and
an upper conductive pattern disposed on the conductive layer,
wherein the lower hole has a first width at a portion closer to the lower conductive pattern than a second width that is greater than the first width, the second width is disposed at a portion closer to the upper conductive pattern than the first width, and
the width of the upper hole is greater than a maximum width of the lower hole.

6. The substrate of claim 5, wherein
the lower hole has a lower width at a portion in contact with the lower conductive pattern, and the upper hole has an upper width at a portion in contact with the upper conductive pattern, and
a ratio of the upper width to the lower width is greater than about 1 and equal to or smaller than about 3.

7. The substrate of claim 5, further comprising
a connection conductive pattern disposed within the via hole and connected to the lower conductive pattern and the upper conductive pattern.

8. The substrate of claim 1, wherein
the insulation layer further includes a first insulation layer disposed in the second portion,
wherein the upper hole is disposed in the first insulation layer and the conductive layer.

9. The substrate of claim 1, further comprising
a first insulation layer disposed between the insulation layer and the conductive layer,
wherein the upper hole further includes a portion in the first insulation layer, and
the width of the upper hole in the first insulation layer is approximately equal to the width of the upper hole in the conductive layer.

10. A substrate comprising:
an insulation layer;
a conductive layer disposed on the insulation layer; and
a via hole configured to include:
a lower hole disposed in a first portion of the insulation layer,
an upper hole disposed in a second portion of the insulating layer disposed above the first portion of the insulation layer and in the conductive layer, and
a middle hole disposed between the lower hole and the upper hole,
wherein a width of the upper hole is greater than that of the lower hole,
a first width of the upper hole in the second portion and a second width of the upper hole in the conductive layer are substantially equal to each other, and
a cross-section of a sidewall of the middle hole has a curved shape.

11. The substrate of claim 10, further comprising:
a lower conduction pattern disposed below the first portion; and
an upper conductive pattern disposed on the conductive layer,
wherein the lower hole has a first width at a portion closer to the lower conductive pattern than a second width that is greater than the first width, the second width is disposed at a portion closer to the upper conductive pattern than the first width, and
the width of the upper hole is greater than a maximum width of the lower hole.

12. The substrate of claim 11, wherein
the lower hole has a lower width at a portion in contact with the lower conductive pattern, and the upper hole has an upper width at a portion in contact with the upper conductive pattern, and
a ratio of the upper width to the lower width is greater than about 1 and equal to or smaller than about 3.

13. The substrate of claim 10, wherein
the insulation layer further includes a first insulation layer disposed in the second portion,
wherein the upper hole is disposed in the first insulation layer and the conductive layer.

14. The substrate of claim 10, further comprising
a first insulation layer disposed between the insulation layer and the conductive layer,
wherein the upper hole further includes a portion in the first insulation layer, and
the width of the upper hole in the first insulation layer is approximately equal to the width of the upper hole in the conductive layer.

15. The substrate of claim 14, wherein
a central portion of the lower hole and a central portion of the upper hole are not vertically aligned.

16. A manufacturing method of a substrate, comprising:
forming an insulation layer;
forming a conductive layer on the insulating layer;
forming a first hole by first removing the conductive layer and the insulation layer by irradiating a first laser;
forming a second hole by second removing the insulation layer by irradiating a second laser; and
forming a third hole by third removing the conductive layer and the insulation layer by irradiating a third laser.

17. The manufacturing method of claim 16, wherein
the first laser and the third laser are YAG lasers, and
the second laser is a carbon dioxide gas laser.

18. The manufacturing method of claim 17, wherein
the conductive layer is hardly removed in the irradiating of the second laser.

19. The manufacturing method of claim 18, wherein
the insulation layer is impregnated with a glass fiber, and
the glass fiber of the insulating layer is processed in the irradiating of the second laser.

20. The manufacturing method of claim 18, wherein
a width of the first hole in the conductive layer is formed to be narrower than a width of the second hole in the insulation layer before the irradiating of the third laser, and
a width of the third hole in the conductive layer and a width of the third hole in the insulating layer are formed to be substantially the same in the irradiating of the third laser.

21. A substrate comprising:
an insulation layer;
a conductive layer disposed on the insulation layer; and
a via hole configured to include:
a lower hole disposed in a first portion of the insulation layer, and
an upper hole disposed in a second portion of the insulating layer disposed above the first portion of the insulation layer and in the conductive layer and connected to the lower hole,
wherein a width of the upper hole is greater than that of the lower hole, and
a sidewall of the upper hole in the second portion and the conductive layer extend along a thickness direction of the substrate.

22. The substrate of claim 21, wherein a sidewall of the lower hole extend at an angle relative to the thickness direction.

23. The substrate of claim 21, wherein the conductive layer does not protrude toward an interior of the via hole.

24. The substrate of claim 21, wherein
the insulation layer further includes a first insulation layer disposed in the second portion,
wherein the upper hole is disposed in the first insulation layer and the conductive layer.

25. The substrate of claim 21, wherein
the via hole further includes a middle hole disposed between the lower hole and the upper hole, and
a cross-section of the sidewall of the middle hole has a curved shape.
